(19) United States
(12) Patent Application Publication
(10) Pub. No.: US 2018/0301484 A1
(43) Pub. Date: Oct. 18, 2018

(54) IMAGE SENSORS WITH HIGH DYNAMIC RANGE AND AUTOFOCUSING HEXAGONAL PIXELS

(71) Applicant: SEMICONDUCTOR COMPONENTS INDUSTRIES, LLC, Phoenix, AZ (US)

(72) Inventors: Brian Anthony VAARTSTRA, Nampa, ID (US); Nathan Wayne CHAPMAN, Meridian, ID (US)

(73) Assignee: SEMICONDUCTOR COMPONENTS INDUSTRIES, LLC, Phoenix, AZ (US)

(21) Appl. No.: 15/488,646

(22) Filed: Apr. 17, 2017

(51) Int. Cl. H01L 27/146; H04N 5/369

(52) U.S. Cl. CPC H01L 27/14607; H04N 5/369; H01L 27/14645; H01L 27/1463; H01L 27/14621; H01L 27/14627

(57) ABSTRACT

An image sensor may include phase detecting and autofocusing (PDAF) pixels. Each PDAF pixel may be hexagonal may be divided into two or more photodiode regions. A semi-spherical microlens may be formed over each PDAF pixel. Each PDAF pixel may be further divided into an inner sub-pixel portion and an outer sub-pixel portion to provide high dynamic range (HDR) functionality. The outer sub-pixel portion may be further divided into two or more photodiode regions to provide depth sensing capability. A semi-toroidal microlens may be formed over each PDAF HDR pixel. Each PDAF HDR pixel may also have a snowflake-like shape or some irregular shape. Smaller interstitial pixels may be dispersed among the larger snowflake-like pixels.

### BACKGROUND

This relates generally to imaging systems and, more particularly, to imaging systems with high dynamic range functionalities and phase detection capabilities.

Modern electronic devices such as cellular telephones, cameras, and computers often use digital image sensors. Imager sensors (sometimes referred to as imagers) may be formed from a two-dimensional array of image sensing pixels. Each pixel receives incident photons (light) and converts the photons into electrical signals. Image sensors are sometimes designed to provide images to electronic devices using a Joint Photographic Experts Group (JPEG) format.

Some applications such as automatic focusing and three-dimensional (3D) imaging may require electronic devices to provide stereo and/or depth sensing capabilities. For example, to bring an object of interest into focus for an image capture, an electronic device may need to identify the distances between the electronic device and object of interest. To identify distances, conventional electronic devices use complex arrangements. Some arrangements require the use of multiple image sensors and camera lenses that capture images from various viewpoints. Other arrangements require the addition of lenticular arrays that focus incident light on sub-regions of a two-dimensional pixel array. Due to the addition of components such as additional image sensors or complex lens arrays, these arrangements lead to reduced spatial resolution, increased cost, and increased complexity.

Conventional imaging systems also may have images with artifacts associated with low dynamic range. Scenes with bright and dark portions may produce artifacts in conventional image sensors, as portions of the low dynamic range images may be over exposed or under exposed. Multiple low dynamic range images may be combined into a single high dynamic range image, but this typically introduces artifacts, especially in dynamic scenes.

It is within this context that the embodiments herein arise.

### BRIEF DESCRIPTION OF THE DRAWINGS

FIG. 1 is a schematic diagram of an illustrative electronic device with an image sensor that may include phase detection pixels in accordance with an embodiment.

FIG. 2A is a cross-sectional side view of illustrative phase detection pixels having photosensitive regions with different and asymmetric angular responses in accordance with an embodiment.

FIGS. 2B and 2C are cross-sectional views of the phase detection pixels of FIG. 2A in accordance with an embodiment.

FIG. 3 is a diagram of illustrative signal outputs of photosensitive regions of depth sensing pixels for incident light striking the depth sensing pixels at varying angles of incidence in accordance with an embodiment.

FIG. 4 is a perspective view of an array of hexagonal image sensor pixels in accordance with an embodiment.

FIGS. 5A-5D are diagrams showing how each hexagonal image sensor pixel may be divided into multiple photosensitive regions in accordance with at least some embodiments.

FIGS. 6A-6D are diagrams showing various configurations of high dynamic range (HDR) hexagonal pixels in accordance with at least some embodiments.

FIGS. 7A-7C are cross-sectional side views showing various lens options for the center sub-pixel in an HDR pixel in accordance with at least some embodiments.

FIGS. 8A and 8B are perspective views of an array of snowflake image sensor pixels in accordance with at least some embodiments.

FIGS. 9A-9I are diagrams showing how each snowflake image sensor pixel may be divided into multiple photosensitive regions and can support high dynamic range functionality in accordance with at least some embodiments.

FIGS. 10A and 10B are diagrams showing how each image sensor pixel may have an irregular polygonal shape in accordance with at least some embodiments.

FIGS. 11A and 11B are diagrams showing how each microlens may have an irregular polygonal shape in accordance with at least some embodiments.

### DETAILED DESCRIPTION

Embodiments of the present invention relate to image sensors with high dynamic range (HDR) functionalities and depth sensing capabilities.

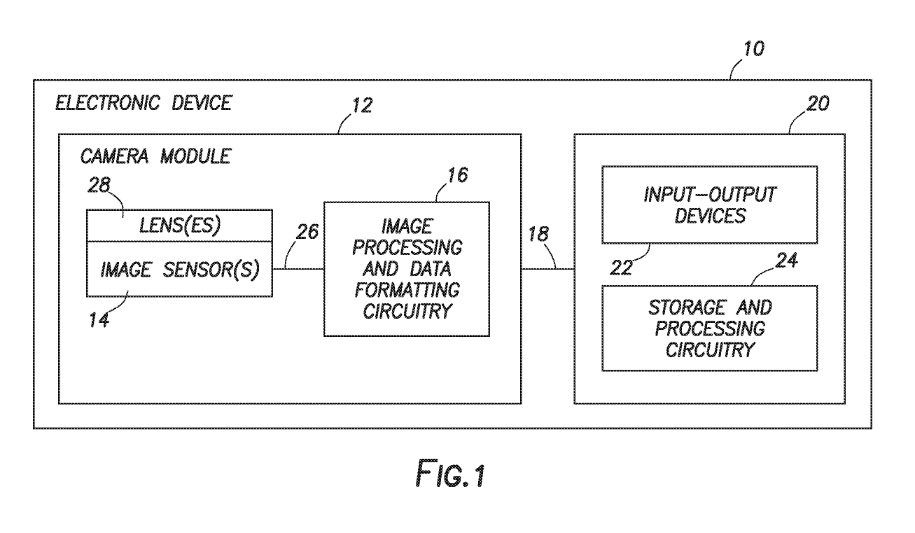

An electronic device with a digital camera module is shown in FIG. 1. Electronic device 10 may be a digital camera, a computer, a cellular telephone, a medical device, or other electronic device. Camera module 12 (sometimes referred to as an imaging device) may include image sensor 14 and one or more lenses 28. During operation, lenses 28 (sometimes referred to as optics 28) focus light onto image sensor 14. Image sensor 14 includes photosensitive elements (e.g., pixels) that convert the light into digital data. Image sensors may have any number of pixels (e.g., hundreds, thousands, millions, or more). A typical image sensor may, for example, have millions of pixels (e.g., megapixels). As examples, image sensor 14 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc.

Still and video image data from image sensor 14 may be provided to image processing and data formatting circuitry 16 via path 26. Image processing and data formatting circuitry 16 may be used to perform image processing functions such as automatic focusing functions, depth sensing, data formatting, adjusting white balance and exposure, implementing video image stabilization, face detection, etc. For example, during automatic focusing operations, image processing and data formatting circuitry 16 may process data gathered by phase detection pixels in image sensor 14 to determine the magnitude and direction of lens movement (e.g., movement of lens 28) needed to bring an object of interest into focus.

Image processing and data formatting circuitry 16 may also be used to compress raw camera image files if desired (e.g., to Joint Photographic Experts Group or JPEG format). In a typical arrangement, which is sometimes referred to as a system on chip (SOC) arrangement, camera sensor 14 and image processing and data formatting circuitry 16 are implemented on a common integrated circuit.

The use of a single integrated circuit to implement camera sensor 14 and image processing and data formatting circuitry 16 can help to reduce costs. This is, however, merely illustrative. If desired, camera sensor 14 and image processing and data formatting circuitry 16 may be implemented using separate integrated circuits. If desired, camera sensor 14 and image processing circuitry 16 may be formed on separate semiconductor substrates. For example, camera sensor 14 and image processing circuitry 16 may be formed on separate substrates that have been stacked.

Camera module 12 may convey acquired image data to host subsystems 20 over path 18 (e.g., image processing and data formatting circuitry 16 may convey image data to subsystems 20). Electronic device 10 typically provides a user with numerous high-level functions. In a computer or advanced cellular telephone, for example, a user may be provided with the ability to run user applications. To implement these functions, host subsystem 20 of electronic device 10 may include storage and processing circuitry 24 and input-output devices 22 such as keypads, input-output ports, joysticks, and displays. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, or other processing circuits.

Image sensors may sometimes be provided with high dynamic range functionalities (e.g., to use in low light and bright environments to compensate for high light points of interest in low light environments and vice versa). To provide high dynamic range functionalities, image sensor 14 may include high dynamic range pixels.

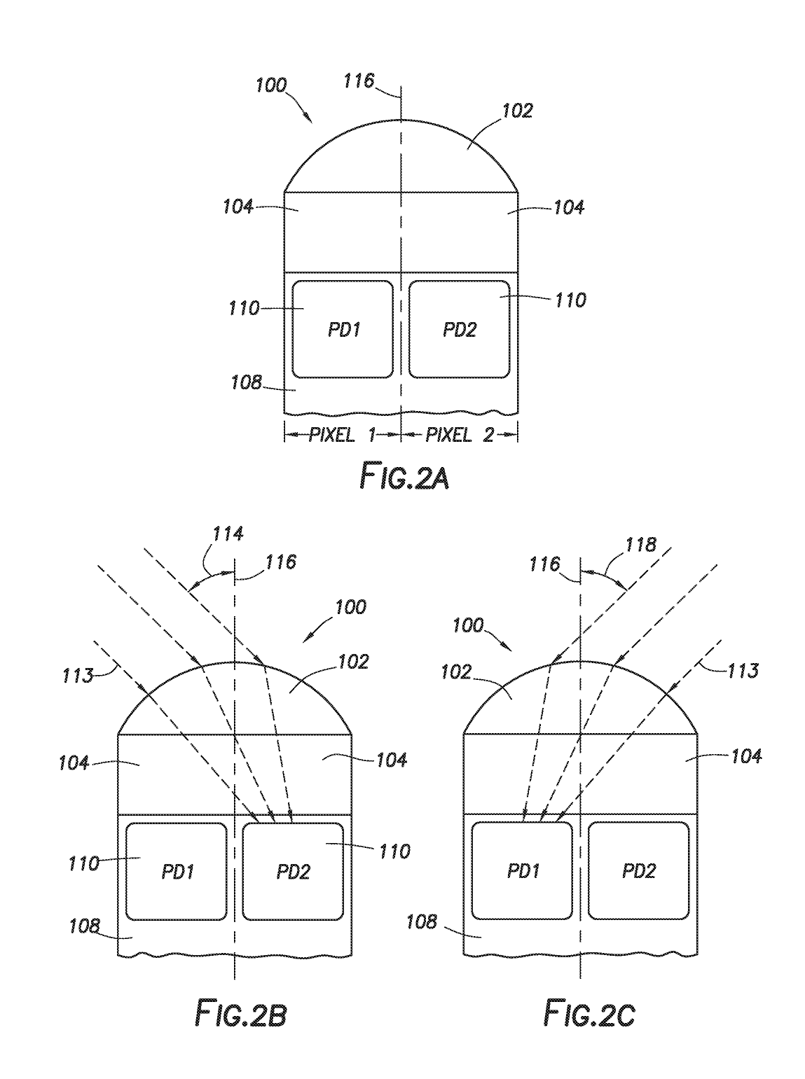

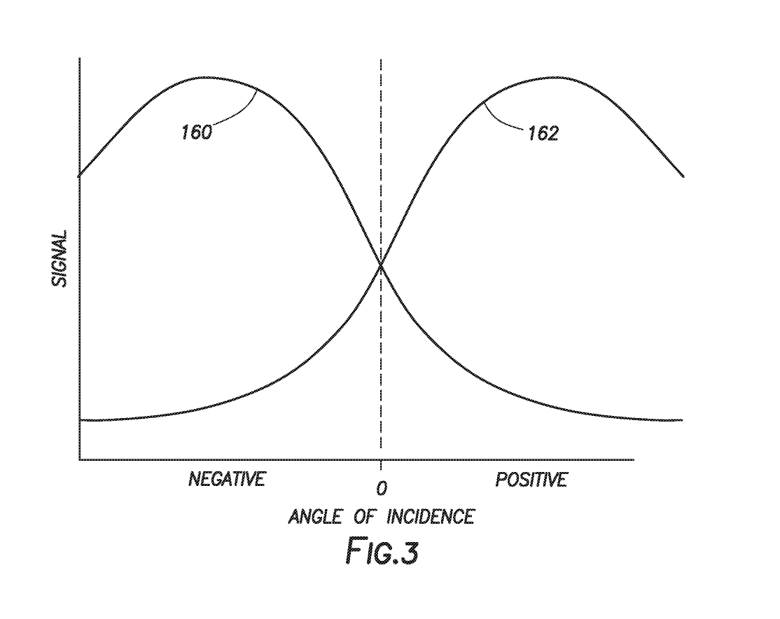

Image sensors may also be provided with depth sensing capabilities (e.g., to use in automatic focusing applications, 3D imaging applications such as machine vision applications, etc.). To provide depth sensing capabilities, image sensor 14 may include phase detection pixel groups such as phase detection pixel group 100 shown in FIG. 2A. If desired, pixel groups that provide depth sensing capabilities may also provide high dynamic range functionalities.

FIG. 2A is an illustrative cross-sectional view of pixel group 100. In FIG. 2A, phase detection pixel group 100 is a pixel pair. Pixel pair 100 may include first and second pixels such Pixel 1 and Pixel 2. Pixel 1 and Pixel 2 may include photosensitive regions such as photosensitive regions 110 formed in a substrate such as silicon substrate 108. For example, Pixel 1 may include an associated photosensitive region such as photodiode PD1, and Pixel 2 may include an associated photosensitive region such as photodiode PD2. A microlens may be formed over photodiodes PD1 and PD2 and may be used to direct incident light towards photodiodes PD1 and PD2.

The arrangement of FIG. 2A in which microlens 102 covers two pixel regions may sometimes be referred to as a 2×1 or 1×2 arrangement because there are two phase detection pixels arranged consecutively in a line. In an alternate embodiment, three phase detection pixels may be arranged consecutively in a line in what may sometimes be referred to as a 1×3 or 3×1 arrangement. In other embodiments, phase detection pixels may be grouped in a 2×2 or 2×4 arrangement. In general, phase detection pixels may be arranged in any desired manner.

Color filters such as color filter elements 104 may be interposed between microlens 102 and substrate 108. Color filter elements 104 may filter incident light by only allowing predetermined wavelengths to pass through color filter elements 104 (e.g., color filter 104 may only be transparent to the wavelengths corresponding to a green color, a red color, a blue color, a yellow color, a cyan color, a magenta color, visible light, infrared light, etc.). Color filter 104 may be a broadband color filter. Examples of broadband color filters include yellow color filters (e.g., yellow color filter material that passes red and green light) and clear color filters (e.g., transparent material that passes red, blue, and green light). In general, broadband filter elements may pass two or more colors of light. Photodiodes PD1 and PD2 may serve to absorb incident light focused by microlens 102 and produce pixel signals that correspond to the amount of incident light absorbed.

Photodiodes PD1 and PD2 may each cover approximately half of the substrate area under microlens 102 (as an example). By only covering half of the substrate area, each photosensitive region may be provided with an asymmetric angular response (e.g., photodiode PD1 may produce different image signals based on the angle at which incident light reaches pixel pair 100). The angle at which incident light reaches pixel pair 100 relative to a normal axis 116 (i.e., the angle at which incident light strikes microlens 102 relative to normal optical axis 116 of lens 102) may be herein referred to as the incident angle or angle of incidence.

An image sensor can be formed using front side illumination imager arrangements (e.g., when circuitry such as metal interconnect circuitry is interposed between the microlens and photosensitive regions) or backside illumination imager arrangements (e.g., when the photosensitive regions are interposed between the microlens and the metal interconnect circuitry). The example of FIGS. 2A, 2B, and 2C in which Pixels 1 and 2 are backside illuminated image sensor pixels is merely illustrative. If desired, Pixels 1 and 2 may be front side illuminated image sensor pixels. Arrangements in which pixels are backside illuminated image sensor pixels are sometimes described herein as an example.

In the example of FIG. 2B, incident light 113 may originate from the left of normal axis 116 and may reach pixel pair 100 with an angle 114 relative to normal axis 116. Angle 114 may be considered a negative angle of incident light. Incident light 113 that reaches microlens 102 at a negative angle such as angle 114 may be focused towards photodiode PD2. In this scenario, photodiode PD2 may produce relatively high image signals, whereas photodiode PD1 may produce relatively low image signals (e.g., because incident light 113 is not focused towards photodiode PD1).

In the example of FIG. 2C, incident light 113 may originate from the right of normal axis 116 and reach pixel pair 100 with an angle 118 relative to normal axis 116.

Angle 118 may be considered a positive angle of incident light. Incident light that reaches microlens 102 at a positive angle such as angle 118 may be focused towards photodiode PD1 (e.g., the light is not focused towards photodiode PD2). In this scenario, photodiode PD2 may produce an image signal output that is relatively low, whereas photodiode PD1 may produce an image signal output that is relatively high.

The positions of photodiodes PD1 and PD2 may sometimes be referred to as asymmetric or displaced positions because the center of each photosensitive area 110 is offset from (i.e., not aligned with) optical axis 116 of microlens 102. Due to the asymmetric formation of individual photodiodes PD1 and PD2 in substrate 108, each photosensitive area 110 may have an asymmetric angular response (e.g., the signal output produced by each photodiode 110 in response to incident light with a given intensity may vary based on an angle of incidence). It should be noted that the example of FIGS. 2A-2C where the photodiodes are adjacent is merely illustrative. If desired, the photodiodes may not be adjacent (i.e., the photodiodes may be separated by one or more intervening photodiodes).

In the plot of FIG. 3, an example of the image signal outputs of photodiodes PD1 and PD2 of pixel pair 100 in response to varying angles of incident light is shown. Line 160 may represent the output image signal for photodiode PD2 whereas line 162 may represent the output image signal for photodiode PD1. For negative angles of incidence, the output image signal for photodiode PD2 may increase (e.g., because incident light is focused onto photodiode PD2) and the output image signal for photodiode PD1 may decrease (e.g., because incident light is focused away from photodiode PD1). For positive angles of incidence, the output image signal for photodiode PD2 may be relatively small and the output image signal for photodiode PD1 may be relatively large.

The size and location of photodiodes PD1 and PD2 of pixel pair 100 of FIGS. 2A, 2B, and 2C are merely illustrative. If desired, the edges of photodiodes PD1 and PD2 may be located at the center of pixel pair 100 or may be shifted slightly away from the center of pixel pair 100 in any direction. If desired, photodiodes 110 may be decreased in size to cover less than half of the pixel area.

Output signals from pixel pairs such as pixel pair 100 may be used to adjust the optics (e.g., one or more lenses such as lenses 28 of FIG. 1) in image sensor 14 during automatic focusing operations. The direction and magnitude of lens movement needed to bring an object of interest into focus may be determined based on the output signals from pixel pairs 100.

For example, by creating pairs of pixels that are sensitive to light from one side of the lens or the other, a phase difference can be determined. This phase difference may be used to determine both how far and in which direction the image sensor optics should be adjusted to bring the object of interest into focus.

When an object is in focus, light from both sides of the image sensor optics converges to create a focused image. When an object is out of focus, the images projected by two sides of the optics do not overlap because they are out of phase with one another. By creating pairs of pixels where each pixel is sensitive to light from one side of the lens or the other, a phase difference can be determined. This phase difference can be used to determine the direction and magnitude of optics movement needed to bring the images into phase and thereby focus the object of interest. Pixel blocks that are used to determine phase difference information such as pixel pair 100 are sometimes referred to herein as phase detection pixels, depth-sensing pixels, or phase detection autofocusing (“PDAF”) image sensor pixels.

A phase difference signal may be calculated by comparing the output pixel signal of PD1 with that of PD2. For example, a phase difference signal for pixel pair 100 may be determined by subtracting the pixel signal output of PD1 from the pixel signal output of PD2 (e.g., by subtracting line 162 from line 160). For an object at a distance that is less than the focused object distance, the phase difference signal may be negative. For an object at a distance that is greater than the focused object distance, the phase difference signal may be positive. This information may be used to automatically adjust the image sensor optics to bring the object of interest into focus (e.g., by bringing the pixel signals into phase with one another).

As previously mentioned, the example in FIGS. 2A-2C where phase detection pixel block 100 includes two adjacent pixels is merely illustrative. In another illustrative embodiment, phase detection pixel block 100 may include multiple adjacent pixels that are covered by varying types of microlenses.

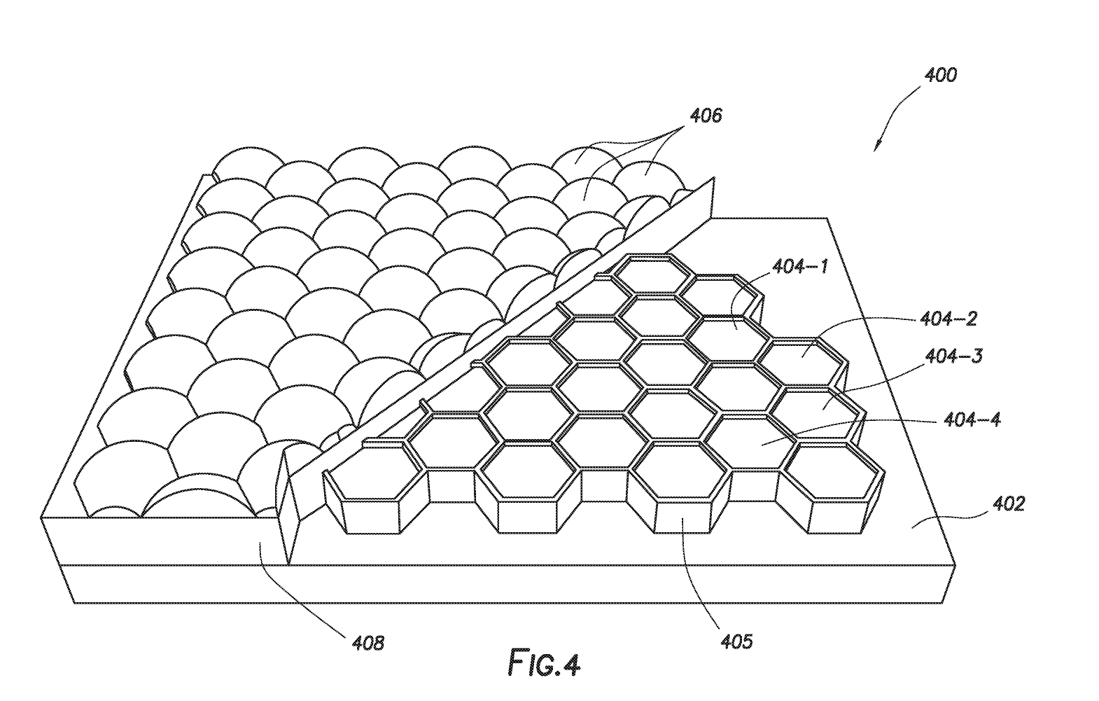

In accordance with an embodiment, phase detection autofocusing (PDAF) pixels may be configured as hexagonal pixels (see, e.g., FIG. 4). As shown in FIG. 4, image sensor 400 may include a semiconductor substrate 402 (e.g., a p-type substrate in which photosensitive regions are formed), color filter elements 404 formed on substrate 402, a planarization layer 408 formed over substrate 402 and color filter elements 404, and an array of microlenses 406 formed over planarization layer 408.

Color filter elements 404 may be formed in a hexagonally tessellated color filter array (CFA) and may include at least a first color filter element 404-1, a second color filter element 404-2, a third color filter element 404-3, and a fourth color filter element 404-4. Each of color filter elements 404-1, 404-2, 404-3, and 404-4 may be configured to filter different wavelengths or color. This configuration in which the color filter array includes four different types of color filter elements is merely illustrative. If desired, the color filter array may include only three different types of color filters (e.g., only red, green, and blue color filter elements) or more than four different types of color filter elements.

Color filter elements 404 can be inserted into corresponding color filter housing structures 405. Color filter housing structures 405 may include an array of slots in which individual color filter elements may be inserted. An array of color filter elements that are contained within such types of housing structures are sometimes referred to as a CFA-in-a-box (abbreviated as “CIAB”). Color filter array housing structures 405 may have walls that are formed from a dielectric material (e.g., silicon oxide) and may serve to provide improved light guiding capabilities for directing light to desired image sensor pixels. In the example of FIG. 4, CIAB 405 may have hexagonal slots. In general, CIAB 405 may have slots of any suitable shape.

In another embodiment, there may be one or more sub-arrays of image sensor pixels within the complete array of pixels that have different patterns of color filter elements than the first pattern. Thus the sensor array may contain regions of monochrome pixels, and other regions of tri-colored pixels (typically referred to as “RGB” or “CMY” color filter pixel schemes). Each sub-array may also be constructed such that each sub-array filters different wavelength ranges. These examples are merely a few of the possible configurations that could be used to create sub-arrays within the entire sensor array.

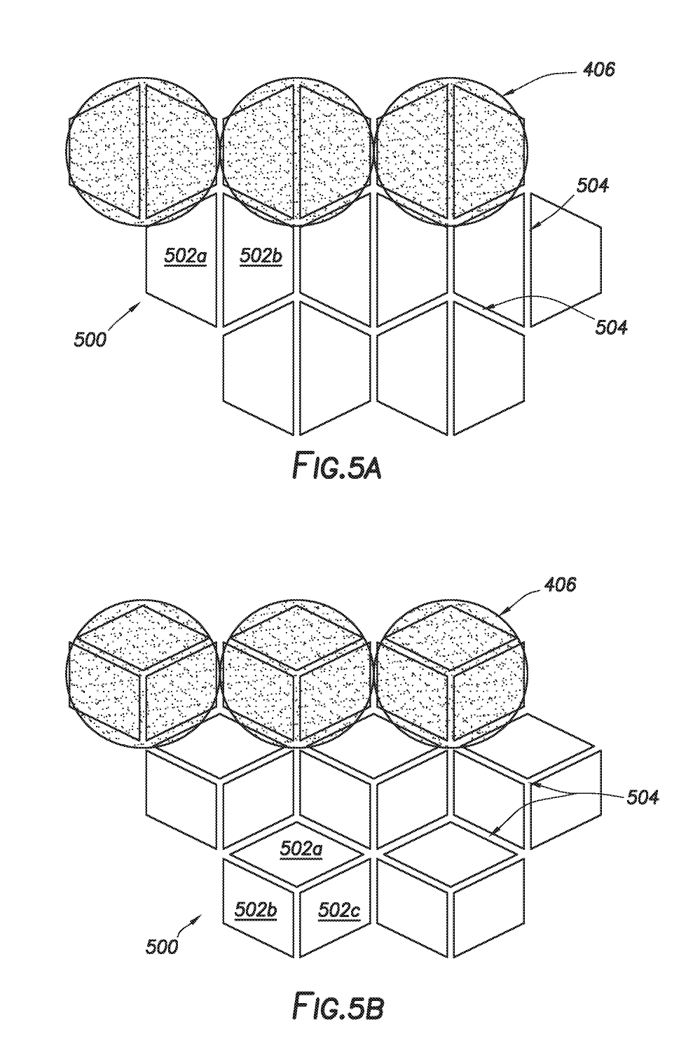

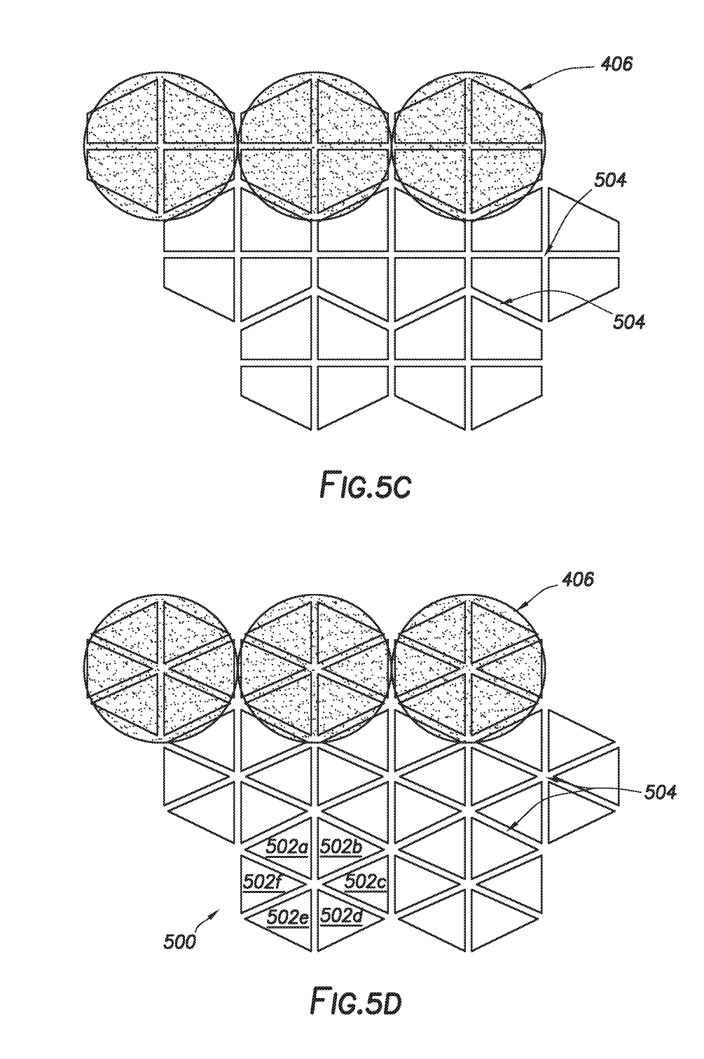

The photodiodes formed in substrate 402 underneath the color filter array may also be formed in a hexagonally tessellated array configuration. FIG. 5A is a diagram showing how each hexagonal image sensor pixel may be divided into two photosensitive regions. As shown in FIG. 5A, each pixel 500 may be divided into a first photodiode region 502a and a second photodiode region 502b. The two separate photodiode regions can help provide phase detection capabilities, as described above in connection with FIG. 2.

Photodiode regions 502a and 502b may correspond to n-type doped photodiode regions in the semiconductor substrate. There may be respective sub-pixel circuitry in the substrate such as transfer gates, floating diffusion regions, and reset gates of pixel 400 that is coupled to the photodiode regions, which are not shown so as to not unnecessarily obscure the present embodiments.

A semi-spherical microlens 406 may be formed over each pixel 500. In the arrangement in which the image sensor is a backside illuminated (“BSI”) image sensor, adjacent pixels 500 may be separated using backside deep trench isolation (“BDTI”) structures such as BDTI structures 504. Deep trench isolation structures 504 may also be formed within each pixel to physically and electrically isolate the two internal photodiode regions 502a and 502b.

FIG. 5B shows another example in which each hexagonal pixel 500 may be divided into three separate photodiode regions 502a, 502b, and 502c. Trisecting PDAF pixels in this way can help provide improved depth sensing capabilities. As shown in FIG. 5B, BDTI structures 504 may also be formed within each pixel 500 to physically and electrically isolate the three internal photodiode regions 502a, 502b, and 502c.

FIG. 5C shows another example in which each hexagonal pixel 500 may be divided into four separate photodiode regions. Each of these sub-divided regions may have a quadrilateral footprint (when viewed from the top as shown in FIG. 5C). Quadsecting PDAF pixels in this way can help further improve depth sensing capabilities. As shown in FIG. 5C, BDTI structures 504 may also be formed within each pixel 500 to physically and electrically isolate the four internal photodiode regions.

FIG. 5D shows yet another example in which each hexagonal pixel 500 may be divided into six separate photodiode regions 502a, 502b, 502c, 502d, 502e, and 502f. Each of these regions 502 may have a triangular footprint (when viewed from the top as shown in FIG. 5D). Dividing PDAF pixels in this way can help further improve depth sensing capabilities. As shown in FIG. 5D, BDTI structures 504 may also be formed within each pixel 500 to physically and electrically isolate the six internal photodiode regions 502a, 502b, 502c, 502d, 502e, and 502f.

The examples of FIGS. 5A-5D in which hexagonal pixel 500 is divided into two, three, four, or six sub-regions is merely illustrative and does not serve to limit the scope of the present embodiments. If desired, each hexagonal pixel can be subdivided into at least five photodiode regions, more than six photodiode regions, or any suitable number of sub-regions of the same or different shape/area.

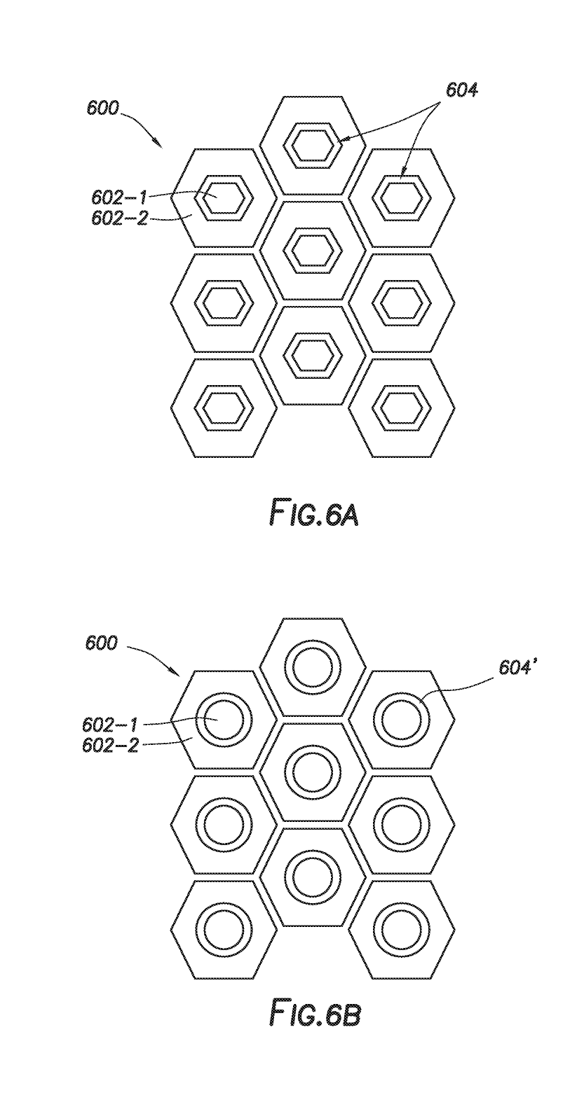

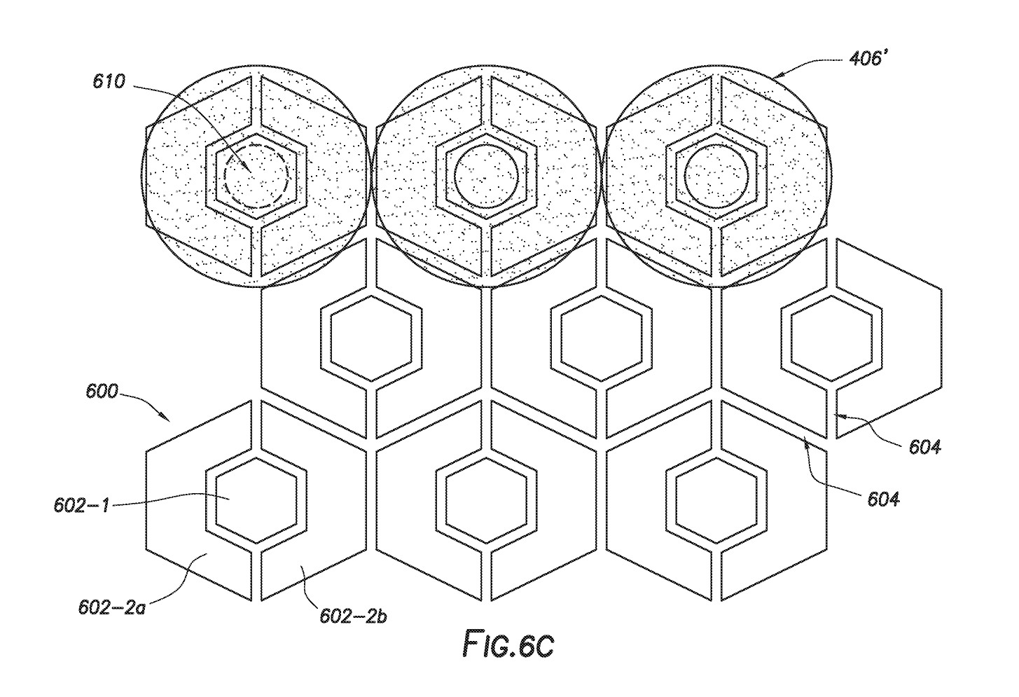

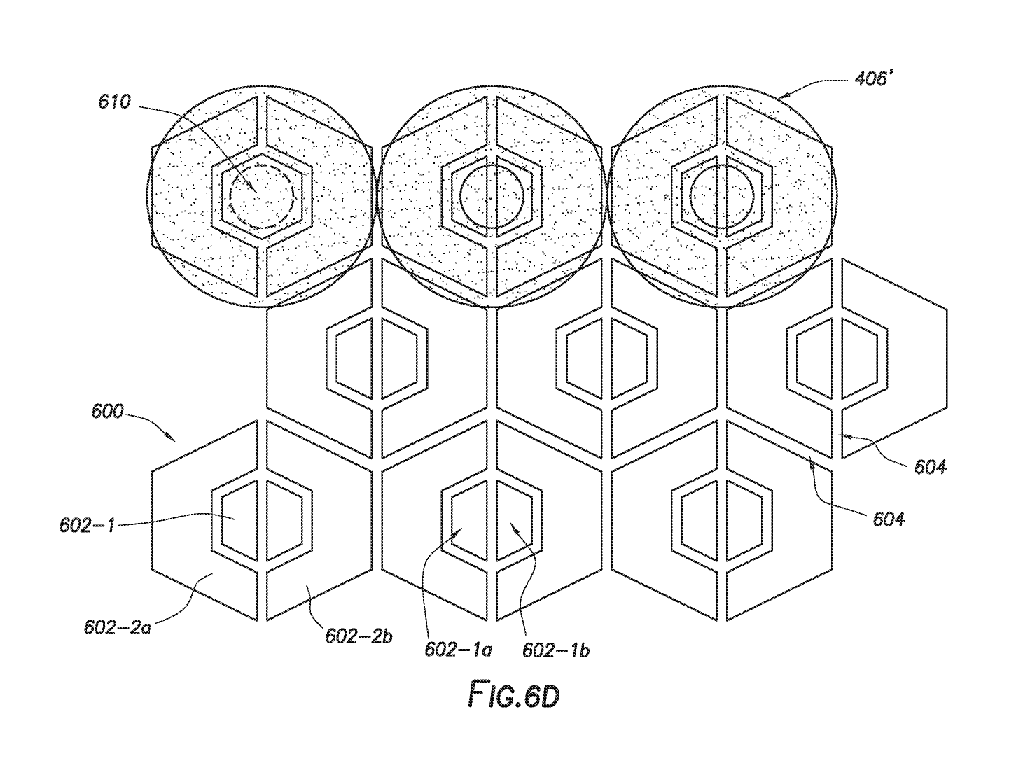

In accordance with another embodiment, hexagonal image sensor pixels can also be subdivided into light collecting regions having different areas to provide high dynamic range (HDR) functionality. Pixel 600 of FIG. 6A may include a first sub-pixel 602-1, which may be referred to as the inner sub-pixel. Inner sub-pixel 602-1 may be completely surrounded by a second sub-pixel 602-2, which may be referred to as the outer sub-pixel. Inner sub-pixel 602-1 and outer sub-pixel 602-2 may correspond to n-type doped photodiode regions in the semiconductor substrate. There may be respective sub-pixel circuitry in the substrate such as transfer gates, floating diffusion regions, and reset gates of pixel 600 that is coupled to the inner and outer sub-pixels, which are not shown so as to not unnecessarily obscure the present embodiments.

In the example of FIG. 6A, the light collecting area of inner sub-pixel 602-1 is a hexagonal region. Backside deep trench isolation structures 604 may be formed between inner sub-pixel 602-1 and outer sub-pixel 602-2 to provide physical and electrical isolation between sub-pixel regions 602-1 and 602-2. In the example of FIG. 6B, the light collecting area of inner sub-pixel 602-1 is a circular region. Backside deep trench isolation structures 604′ may be formed between inner sub-pixel 602-1 and outer sub-pixel 602-2 to provide physical and electrical isolation between sub-pixel regions 602-1 and 602-2. If desired, inner sub-pixel region 602-1 and surrounding BDTI structures may be triangular, rectangular, pentagonal, octagonal, or have any suitable shape.

FIG. 6C is a diagram showing how each HDR hexagonal image sensor pixel 600 may be further divided into multiple phase detecting regions. As shown in FIG. 6C, the outer sub-pixel region of pixel 600 may be divided into regions 602-2a and 602-2b. A semi-toroidal microlens 406′ may be formed over each pixel 600. Microlens 406′ may have a central region 610 (see dotted region in FIG. 6C) surrounded by a semi-toroid region. In the arrangement in which the image sensor is a backside illuminated (“BSI”) image sensor, adjacent pixels 600 may be separated using BDTI structures 604. Deep trench isolation structures 604 may also be formed within each pixel to physically and electrically isolate not only the inner and outer sub-pixels but also the two outer photodiode regions 602-2a and 602-2b. Configured in this way, image sensor pixel 600 may provide both high dynamic range and phase detecting autofocusing functionalities.

The example of FIG. 6C in which HDR PDAF pixel 600 is divided into two outer sub-regions is merely illustrative and does not serve to limit the scope of the present embodiments. If desired, the outer sub-pixel 602-2 can be divided into at least three photodiode regions (see, e.g., FIG. 5B), at least four photodiode regions (see, e.g., FIG. 5C), at least six photodiode regions (see, e.g., FIG. 5D), or any suitable number of sub-regions of the same or different shape/area.

In another embodiment the central sub-pixel 602-1 can be further subdivided into two or more photodiode regions 602-1a and 602-1b, to impart phase detection capability to both high luminance and low luminance pixels as shown in FIG. 6D. Similarly, deep trench isolation structures 604 may also be formed within each pixel to physically and electrically isolate not only between the inner and outer sub-pixels but also between the two inner photodiode regions 602-1a and 602-1b.

The example of FIG. 6D in which HDR PDAF pixel 600 is divided into two outer sub-regions and the inner portion 602-1 is divided into two sub-regions is merely illustrative and does not serve to limit the scope of the present embodiments. If desired, the inner sup-pixel 602-1 or the outer sub-pixel 602-2 can be divided into at least three photodiode regions (see, e.g., FIG. 5B), at least four photodiode regions (see, e.g., FIG. 5C), at least six photodiode regions (see, e.g., FIG. 5D), or any suitable number of sub-regions of the same or different shape/area. Furthermore, the inner and outer sub-regions need not be subdivided in the same way.

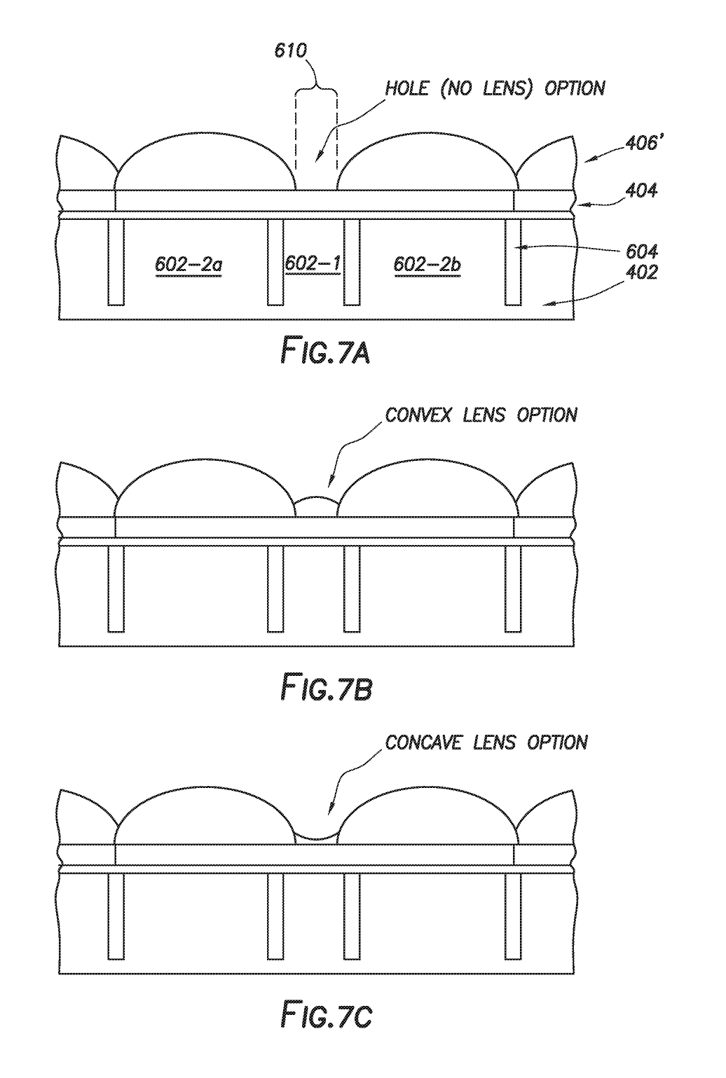

FIGS. 7A-7C are cross-sectional side views showing various lens options for the center sub-pixel region 610 in HDR PDAF pixel 600. As shown in FIG. 7A, backside deep trench isolation structures 604 may be formed from the backside of substrate 402 to separate inner sub-pixel 602-1 from outer sub-pixel regions 602-2a and 602-2b. Color filter array 404 may be formed on the back side (surface) of substrate 402. If desired, a planarization layer may be formed between color filter array 404 and microlens 406′ (see, e.g., planarization layer 408 in FIG. 4). CFA housing structures may optionally be formed between adjacent color filter elements (see, e.g., CIAB structures 405 in FIG. 4).

In the example of FIG. 7A, center region 610 of semi-toroidal microlens 406′ may be flat. The flat region may lack any microlens structure and may be a through hole. The example of FIG. 7B illustrates how center region 610 may include a convex lens, whereas the example of FIG. 7C illustrates how center region 610 may include a concave lens that is formed over inner sub-pixel 602-1. In general, other suitable lens structures may be formed in region 610.

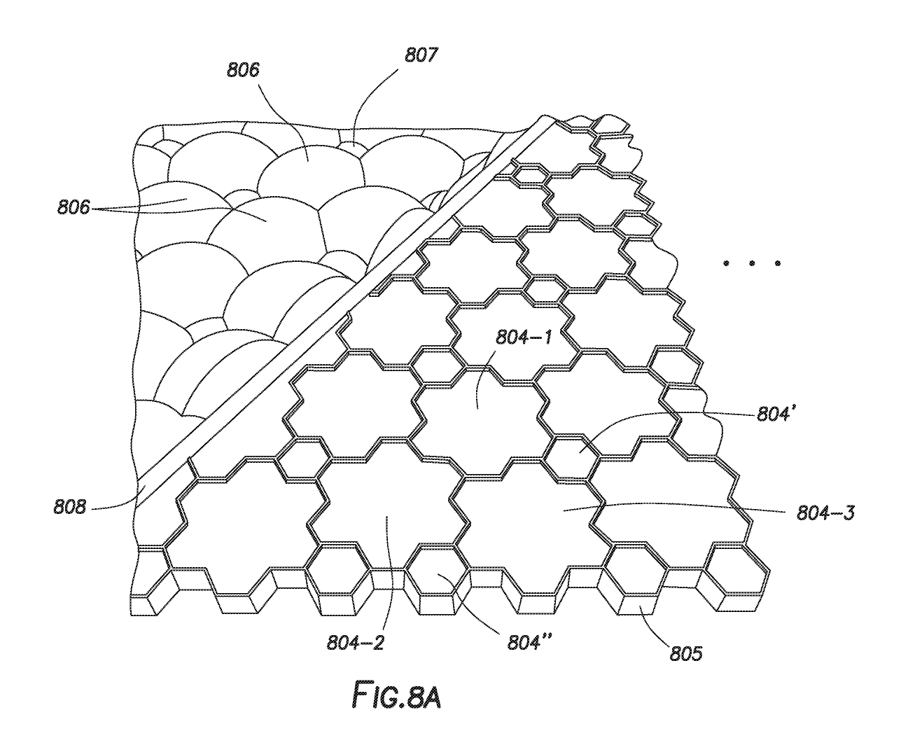

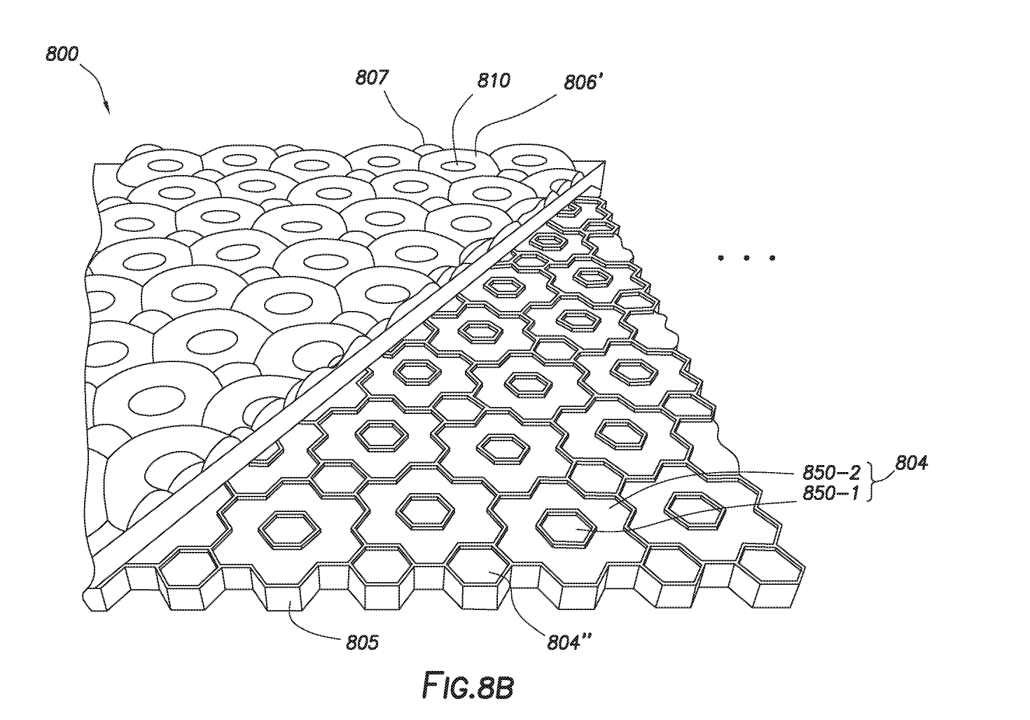

In another suitable arrangement, phase detection autofocusing (PDAF) pixels may be individually configured as an irregular 18-sided polygon (see, e.g., FIG. 8A). As shown in FIG. 8A, image sensor 800 may include color filter elements 804, a planarization layer 808 formed over color filter elements 804, and an array of microlenses 806 formed over planarization layer 808.

Color filter elements 804 may include a first group of color filter elements having a first shape and size and also a second group of color filter elements having a second shape and size that are different than those of the first group. In the example of FIG. 8A, the first group of color filter elements may include color filter elements 804-1, 804-2, and 804-3. Color filter elements 804-1, 804-2, and 804-3 may have the same shape but may be configured to filter light of different wavelengths. The shape of color filter elements 804-1, 804-2, and 804-3 may be divided into seven smaller hexagonal sub-regions and may sometimes be referred to as having a tessellated hexagon group configuration or “snowflake” configuration.

The second group of color filter elements may include hexagonal pixels 804′ and 804″ distributed throughout the entire color filter array. Color filter elements 804′ and 804″ may be configured to filter light of different wavelengths and may be smaller than the snowflake color filter elements 804-1, 804-2, and 804-3. Color filter elements 804′ and 804″ distributed in this way are sometimes referred to as being associated with interstitial pixels or special pixels. The special pixels corresponding to the smaller interstitial pixels may be used in a low power mode and/or a low resolution image sensor mode, used as an infrared pixel, ultraviolet pixel, monochrome pixel, or a high light pixel (in HDR mode), etc.

The exemplary color filter array of FIG. 8A in which the larger snowflake color filter elements of three different colors and the smaller hexagonal color filter elements of two different colors is used is merely illustrative. If desired, the color filter array may include snowflake color filter elements of four or more colors (e.g., green, red, blue, yellow, cyan, magenta, etc.) and smaller interstitial color filter elements of one or more color (e.g., visible, infrared, monochrome, etc.). Furthermore, the entire array can be monochromic, dichromic, trichromic, etc., wherein any area above each hexagonal or tessellated hexagonal group pixel area can be filtered for any desired wavelength range by choosing a certain color filter element.

In another embodiment, there may be one or more sub-arrays of image sensor pixels within the complete array of pixels that have different patterns of color filter elements from the first pattern. Thus, the sensor array may contain regions of monochrome pixels, and other regions of tri-colored pixels (typically referred to as “RGB” or “CMY” color filter pixel schemes). Each sub-array may also be constructed such that each sub-array will filter different wavelength ranges. These examples are merely a few of the possible configurations that could be used to create sub-arrays within the entire sensor array.

The microlens array may include larger microlenses 806 covering the snowflake pixels and smaller microlenses 807 covering the special interstitial pixels. The smaller microlenses 807 may be flat (FIG. 7A), convex (FIG. 7B), concave (FIG. 7C), or some other shape.

The color filter elements of FIG. 8A can be inserted into corresponding color filter housing structures 805. Color filter housing structures 805 may include an array of slots. Color filter array housing structures or CIAB 805 may have walls that are formed from a dielectric material (e.g., silicon oxide) and may serve to provide improved light guiding capabilities for directing light to desired image sensor pixels. In the example of FIG. 8A, CIAB 805 may have snowflake and hexagonal slots. In general, CIAB 805 may have slots of any suitable shape.

FIG. 8B shows another example in which the snowflake image sensor pixels are further subdivided into light collecting regions having different areas to provide high dynamic range (HDR) functionality. As shown in FIG. 8B, each of the 18-gon pixels may be divided into a first inner sub-pixel 850-1 and an outer sub-pixel 850-2 that completely surrounds the inner sub-pixel. Inner sub-pixel 850-1 may have the same shape and size as the special interstitial pixels 804′ and 804″. CIAB 805 may also have walls for separating inner sub-pixel 850-1 from outer sub-pixel 850-2.

Semi-toroidal microlens 806′ may be formed over these HDR pixels. Microlens 806′ may have a central region 810 surrounded by a semi-toroidal region. Central microlens region 810 may be flat (FIG. 7A), convex (FIG. 7B), concave (FIG. 7C), or some other shape.

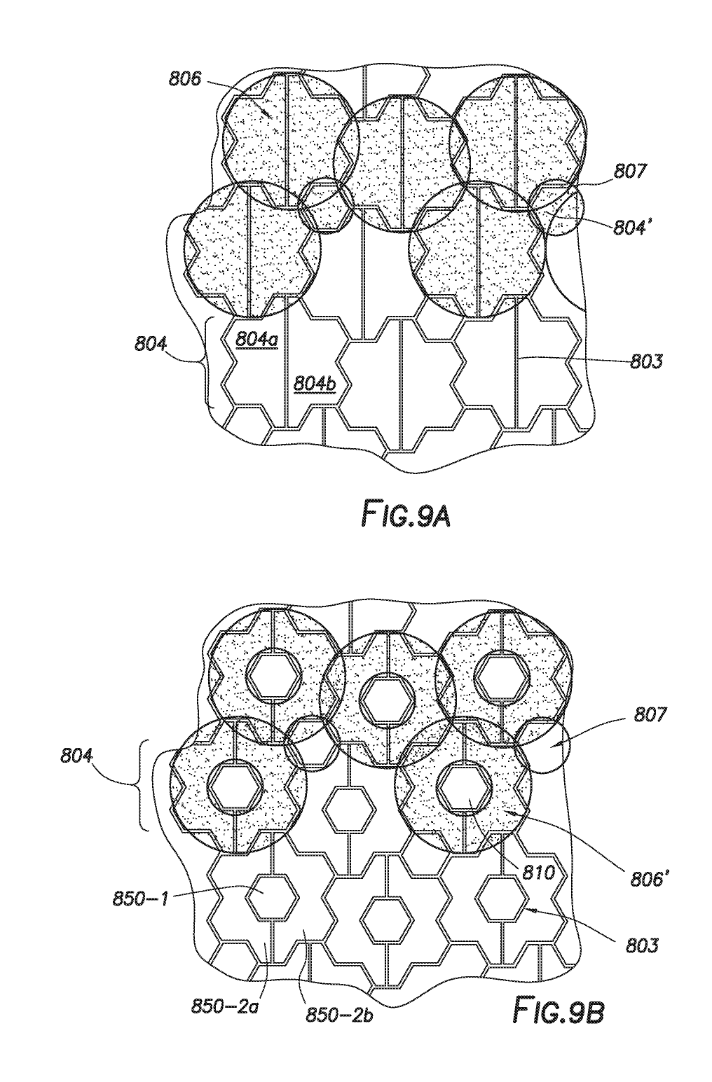

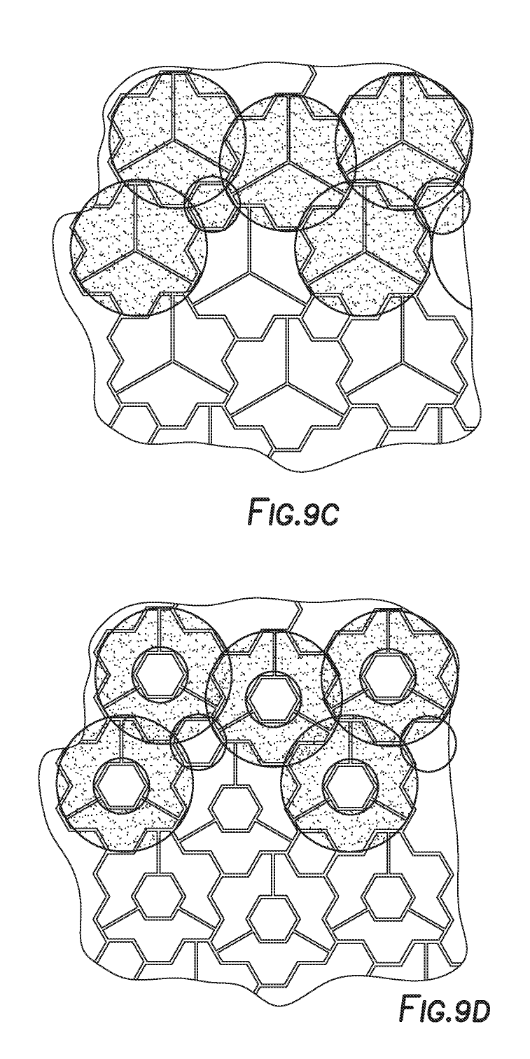

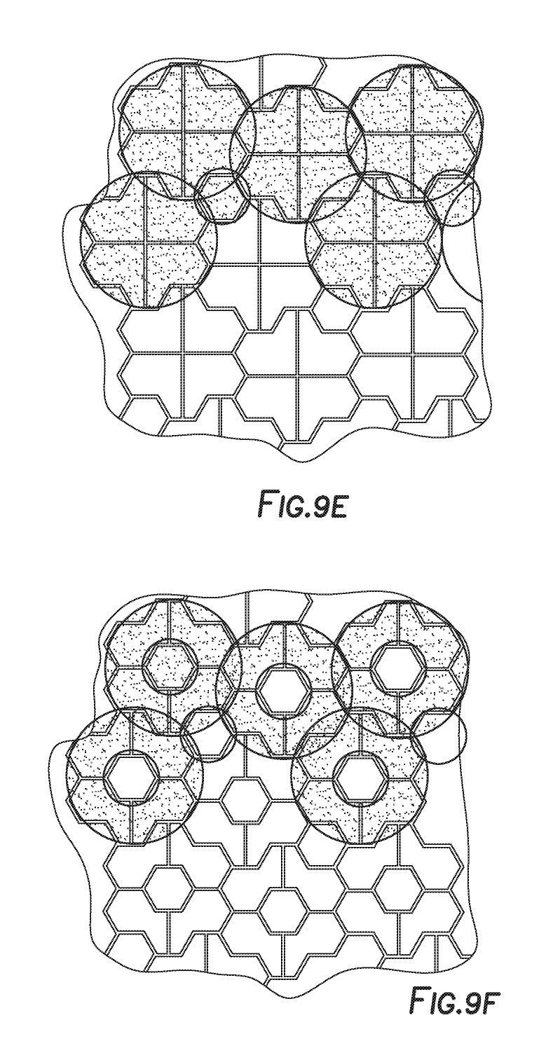

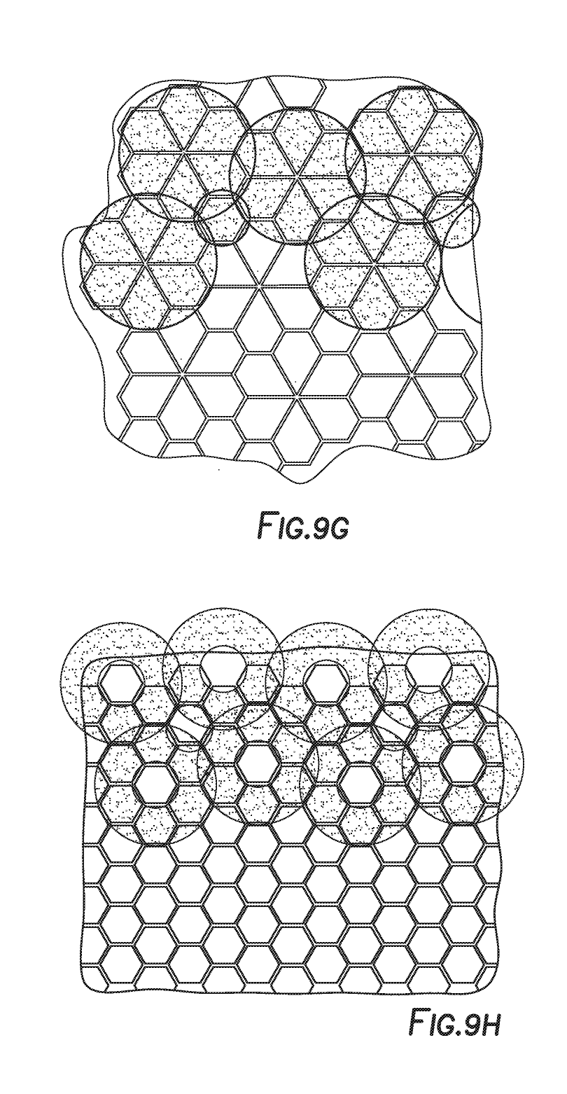

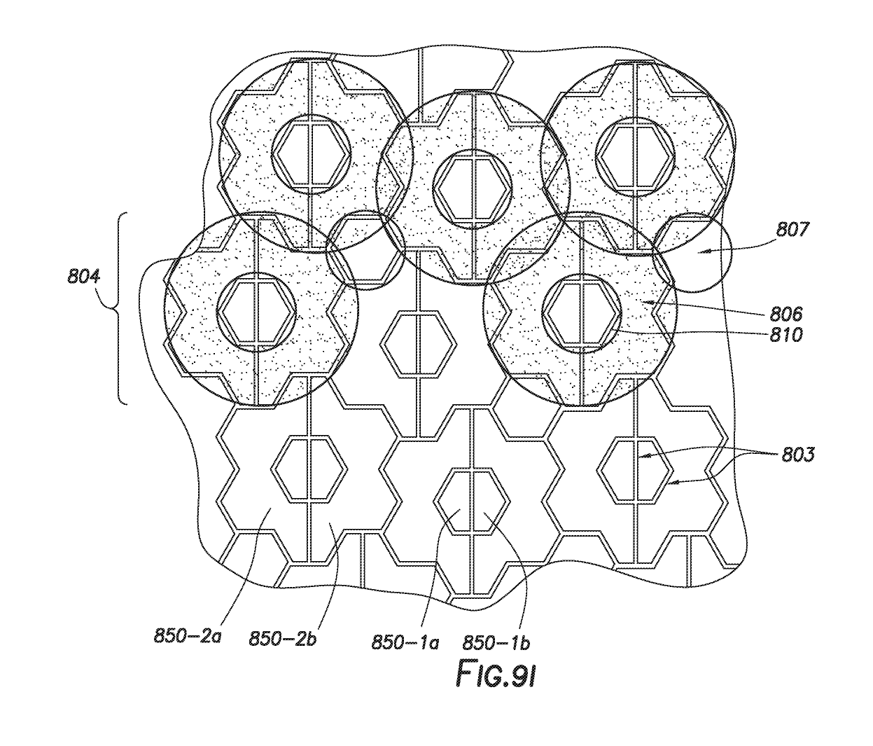

The photodiodes formed in the semiconductor substrate underneath the color filter array of FIGS. 8A and 8B may be formed in a similarly tessellated array configuration. FIG. 9A is a diagram showing how each snowflake image sensor pixel of FIG. 8A may be divided into two photosensitive regions. As shown in FIG. 9A, each pixel 804 may be divided into a first photodiode region 804a and a second photodiode region 804b. The two separate photodiode regions can help provide phase detection capabilities, as described above in connection with FIG. 2. Photodiode regions 804a and 804b may correspond to n-type doped photodiode regions in the semiconductor substrate. There may be respective sub-pixel circuitry in the substrate such as transfer gates, floating diffusion regions, and reset gates of pixel 804 that is coupled to the photodiode regions, which are not shown so as to not unnecessarily obscure the present embodiments.

As shown in FIG. 9A, semi-spherical microlens 806 may be formed over each snowflake pixel 804. In the arrangement in which the image sensor is a BSI image sensor, adjacent pixels 804 and 804′ may be separated using backside deep trench isolation structures 803. Deep trench isolation structures 803 may also be formed within each pixel 804 to physically and electrically isolate the two internal photodiode regions 804a and 804b.

FIG. 9B is a diagram showing how the outer sub-pixel region 850-2 in each HDR snowflake image sensor pixel of FIG. 8B may be further divided into two photosensitive regions. As shown in FIG. 9B, outer sub-pixel 850-2 may be divided into a first photodiode region 850-2a and a second photodiode region 850-2b. The two separate photodiode regions can help provide phase detection capabilities, as described above in connection with FIG. 2.

As shown in FIG. 9B, semi-toroidal microlens 806′ may be formed over each HDR pixel 804. In the arrangement in which the image sensor is a BSI image sensor, adjacent pixels 804 and 804′ may be separated using backside deep trench isolation structures 803. Deep trench isolation structures 803 may also be formed within each pixel 804 to physically and electrically isolate the two internal photodiode regions 850-2a and 850-2b.

FIG. 9C illustrates another variation of the PDAF pixel configuration of FIG. 9A in which each of the snowflake pixels is divided into three photodiode regions. FIG. 9D illustrates another example where the PDAF pixel of FIG. 9C is further adapted to support HDR imaging using semi-toroidal microlenses.

FIG. 9E illustrates another variation of the PDAF pixel configuration of FIG. 9A in which each of the snowflake pixels is divided into four photodiode regions. FIG. 9F illustrates another example where the PDAF pixel of FIG. 9E is further adapted to support HDR imaging using semi-toroidal microlenses.

FIG. 9G illustrates another variation of the PDAF pixel configuration of FIG. 9A in which each of the snowflake pixels is divided into six photodiode regions. FIG. 9H illustrates another example where the PDAF pixel of FIG. 9G is further adapted to support HDR imaging using semi-toroidal microlenses.

In another embodiment, the central sub-pixel of FIG. 9B can be further subdivided into 2 or more photodiode regions 850-1a and 850-1b, to impart phase detection capability to both high luminance and low luminance pixels (see, e.g., FIG. 9I). Similarly, deep trench isolation structures 803 may also be formed within each pixel to physically and electrically isolate not only the inner and outer sub-pixels but also the two inner photodiode regions 850-1a and 850-1b.

The example of FIG. 9I in which HDR PDAF pixel 804 is divided into two outer sub-regions and the inner portion 850-1 is divided into two sub-regions is merely illustrative and does not serve to limit the scope of the present embodiments. If desired, the inner or outer sub-pixel 850-1 and 850-2 can be divided into at least three photodiode regions (see, e.g., FIG. 5B), at least four photodiode regions (see, e.g., FIG. 5C), at least six photodiode regions (see, e.g., FIG. 5D), or any suitable number of sub-regions of the same or different shape/area. Furthermore, the inner and outer sub-regions need not be subdivided in the same way.

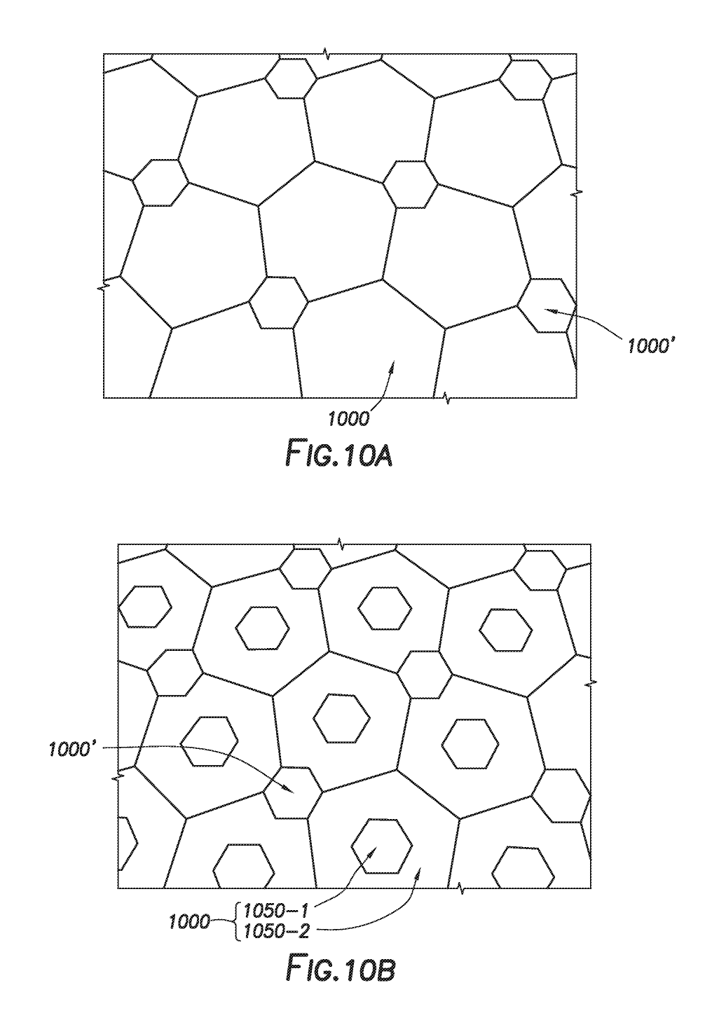

FIGS. 10A and 10B are diagrams showing how each image sensor pixel may have an irregular polygonal shape. As shown in FIG. 10A, a first group of pixels 1000 may have a first irregular polygonal shape, whereas a second group of pixels 1000′ may have a regular hexagonal shape. The first group of pixels may be larger in size than the second group of pixels. Irregularly shapes for the color filter array elements and photodiode regions may be easier to form than regular shapes such as the 18-gon of FIGS. 8-9 and may also help with anti-aliasing since there are no contiguous grid lines as in standard rectangular pixels.

FIG. 10B shows how the larger irregularly shaped pixels may further include a center sub-pixel portion 1050-1. As shown in FIG. 10B, inner sub-pixel portion 1050-1 may be completely surrounded by outer sub-pixel portion 1050-2. Inner sub-pixel 1050-1 may have a hexagonal footprint or other regularly or irregularly shaped footprint. Further, the size of the inner pixel may be smaller or larger than illustrated.

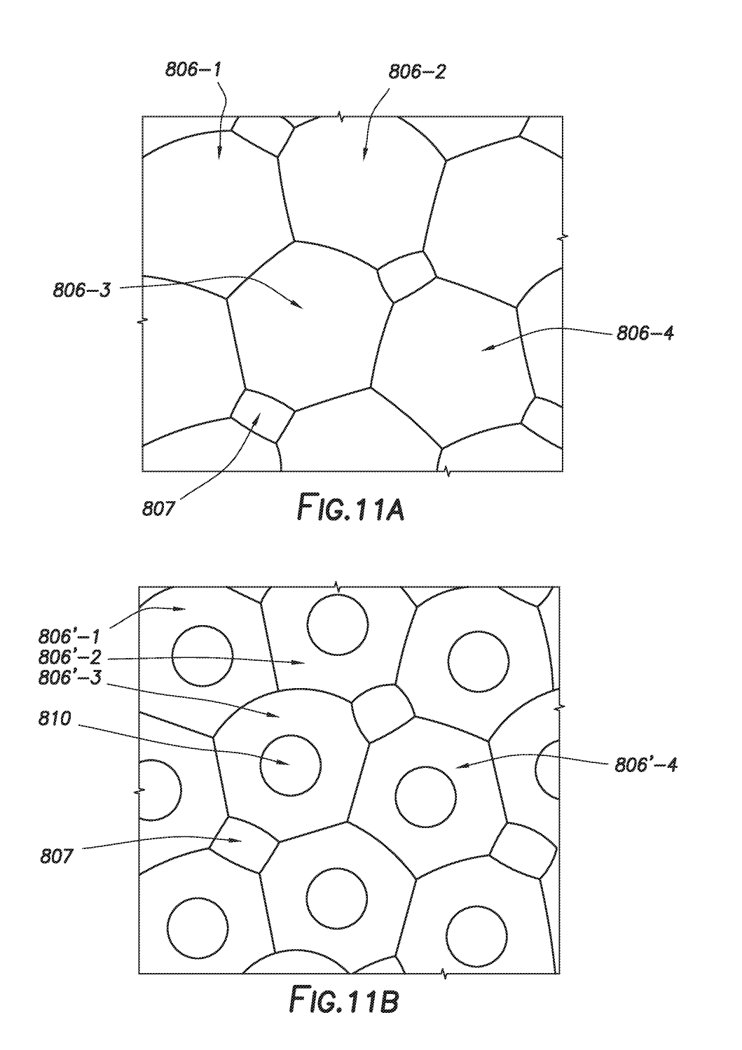

FIGS. 11A and 11B are diagrams showing how each microlens may have an irregular polygonal shape. FIG. 11A shows a top view of a microlens array that can be formed over the pixel configuration of FIG. 10A. As shown in FIG. 11A, the microlens array may include a first microlens 806-1, a second microlens 806-2, a third microlens 806-3, and a fourth microlens 806-4. Microlenses 806 may be formed over color filter elements of at least three or four different colors. Smaller rectangular microlens such as microlenses 807 may be dispersed among the larger irregularly shaped microlens 806 to cover the interstitial pixels 1000′.

FIG. 11B shows a top view of a microlens array that can be formed over the pixel configuration of FIG. 10B. As shown in FIG. 11B, the microlens array may include a first semi-toroidal microlens 806′-1, a second semi-toroidal microlens 806′-2, a third semi-toroidal microlens 806′-3, and a fourth semi-toroidal microlens 806′-4. Microlenses 806′ may be formed over color filter elements of at least three or four different colors. Each semi-toroidal microlens 806′ may also have a center portion 810 that is flat, convex, or concave (see, e.g., FIGS. 7A-7C). Smaller microlens such as microlenses 807 may be dispersed among the semi-toroidal microlens 806′ to cover the interstitial pixels 1000′.

In another embodiment, there may be one or more sub-arrays of image sensor pixels within the complete array of pixels that have different patterns of color filter elements than the first pattern. Thus the sensor array may contain regions of monochrome pixels, and other regions of tri-colored pixels (typically referred to as “RGB” or “CMY” color filter pixel schemes). Each sub-array may also be constructed such that each sub-array filters different wavelength ranges. These examples are merely a few of the possible configurations that could be used to create sub-arrays within the entire sensor array.

In general, the embodiments of FIGS. 1-11 may be applied to image sensors operated in a rolling shutter mode or a global shutter mode. Although a BSI configuration is preferred, the PDAF and HDR pixels described in connection with FIGS. 1-11 may also be applied to a front side illuminated imaging system.

The foregoing is merely illustrative of the principles of this invention and various modifications can be made by those skilled in the art without departing from the scope and spirit of the invention.

1. An image sensor comprising:
a non-rectangular pixel that comprises a first photosensitive region and a second photosensitive region;
a deep trench isolation structure interposed between the first photosensitive region and the second photosensitive region; and
a microlens that covers the first photosensitive region and the second photosensitive region.

2. The image sensor of claim 1, wherein the non-rectangular pixel is hexagonal.

3. The image sensor of claim 1, wherein the first photosensitive region and the second photosensitive region have the same size.

4. The image sensor of claim 1, wherein the non-rectangular pixel further comprises a third photosensitive region that is covered by the microlens.

5. The image sensor of claim 4, wherein the non-rectangular pixel further comprises a fourth photosensitive region that is covered by the microlens.

6. The image sensor of claim 5, wherein the non-rectangular pixel further comprises fifth and sixth photosensitive regions that are covered by the microlens.

7. The image sensor of claim 6, further comprising:
a deep trench isolation structure separating the six photosensitive regions.

8. (canceled)

9. The image sensor of claim 1, further comprising:
a color filter element formed over the non-rectangular pixel; and
a color filter housing structure that surrounds the color filter element.

10. An image sensor comprising:
a non-rectangular pixel that comprises:
an inner sub-pixel; and
an outer sub-pixel that surrounds the inner sub-pixel.

11. The image sensor of claim 10, wherein the non-rectangular pixel is hexagonal.

12. The image sensor of claim 10, wherein the inner sub-pixel is hexagonal.

13. The image sensor of claim 10, wherein the inner sub-pixel is circular.

14. The image sensor of claim 10, wherein the outer sub-pixel completely surrounds the inner sub-pixel.

15. The image sensor of claim 10, further comprising:
a semi-toroidal microlens covering the non-rectangular pixel.

16. The image sensor of claim 10, wherein the outer sub-pixel is divided into multiple photodiode regions.

17. The image sensor of claim 16, wherein the inner sub-pixel is divided into multiple photodiode regions.

18. The image sensor of claim 10, wherein the inner sub-pixel is divided into multiple photodiode regions.

19. An electronic device comprising:
a camera module having an image sensor, the image sensor comprising:
an array of non-rectangular image sensor pixels, each of which is configured to support phase detection and high dynamic range operations.

20. The electronic device of claim 19, wherein each of the non-rectangular image sensor pixels in the array is hexagonal.

21. The electronic device of claim 19, wherein each of the non-rectangular image sensor pixels in the array is divided into a plurality of photodiode regions.

22. The electronic device of claim 19, wherein each of the non-rectangular image sensor pixels in the array comprises an inner sub-pixel portion and an outer sub-pixel portion that surrounds the inner sub-pixel portion.

23. The electronic device of claim 22, wherein the outer sub-pixel portion in each of the non-rectangular image sensor pixels is divided into a plurality of photosensitive regions.

24. The electronic device of claim 19, wherein each of the non-rectangular image sensor pixels in the array comprises a first sub-pixel of a first size and a second sub-pixel of a second size that is greater than the first size.
